(19) United States
(12) Patent Application Publication
(10) Pub. No.: US 2016/0188083 A1
(43) Pub. Date: Jun. 30, 2016

(54) ARRAY SUBSTRATE, TOUCH DISPLAY PANEL AND TOUCH DISPLAY DEVICE

(71) Applicant: BOE TECHNOLOGY GROUP CO., LTD., Beijing (CN)

(72) Inventors: Ling Shi, Beijing (CN); Ming Hsi Wang, Beijing (CN)

(73) Assignee: BOE TECHNOLOGY GROUP CO., LTD., Beijing (CN)

(21) Appl. No.: 14/785,057

(22) PCT Filed: May 23, 2015
(86) PCT No.: PCT/CN2015/079634

§ 371 Date: Oct. 16, 2015

(30) Foreign Application Priority Data
Dec. 9, 2014 (CN) 201410749101.9

(51) Int. Cl. G06F 3/041; H01L 27/32; H01L 51/52; G06F 3/044

(52) U.S. Cl. CPC G06F 3/0416; G06F 3/044; G06F 3/0412; H01L 27/323; H01L 27/3276; H01L 51/5206; H01L 2251/5307

(57) ABSTRACT

An array substrate, a touch display panel and a touch display device are provided to realize the In-cell touch technology in the AMOLED displays. The array substrate includes a base substrate (1) having a plurality of pixel units formed by intersecting data lines (7) and gate lines (2) provided on the base substrate (1), each pixel unit comprises a bottom emission type OLED device and at least one TFT, and the OLED device includes a transparent anode (13). The array substrate further includes a plurality of first electrodes (10) disposed parallel with and in a same layer as the data lines (7) and a plurality of second electrodes (14) disposed parallel with the gate lines (2) and in a same layer as the anode (13). At least one first electrode (10) constitutes a touch driving line (20), and at least one second electrode (14) constitutes a touch sensing line (21).

### TECHNICAL FIELD

Embodiments of the present disclosure relate to an array substrate, a touch display panel and a touch display device.

### BACKGROUND

Active Matrix Organic Light Emitting Diode (AMOLED) display becomes the mainstream of the display device owing to its characteristics such as fast response, high brightness, low power consumption, good view angle, suitable for flexible display, etc. The AMOLED display with touch function emerges in response to the demands on function diversification. Among the various touch technologies, On-cell touch technology and In-cell touch technology are widely used. The On-cell touch technology is usually used in medium and small-sized AMOLED displays. In contrast to the On-cell touch technology, the In-cell touch technology can make the display thinner, and thus its application in AMOLED display earns more attention.

In the case that the In-cell touch technology is applied to the AMOLED display, touch sensors are typically fabricated on the encapsulating substrate and thereafter the encapsulating substrate and the array substrate are bonded together, so that the touch sensors are provided between the array substrate and the encapsulating substrate. However, the above-mentioned structure is restricted to be applied in a glass-cover packaging process and can not be realized in a thin-film packaging process. In a thin-film packaging process, thin films are deposited on the array substrate in a vacuum environment to protect OLED of the array substrate from being corroded by water and oxygen and no glass covers provided on the array substrate are needed, i.e. no encapsulating substrates are provided, so that the touch sensors can not be fabricated on the encapsulating substrate. It can be seen that the In-cell touch technology is significantly restrained from being applied to AMOLED displays.

### SUMMARY

At least one embodiment of the present disclosure provides an array substrate, and the array substrate includes a base substrate. The base substrate has a plurality of pixel units formed by intersecting data lines and gate lines, the data lines and the gate lines are provided on the base substrate, each pixel unit comprises a bottom emission type OLED device and at least one TFT, and the OLED device includes a transparent anode. The array substrate farther includes a plurality of first electrodes disposed parallel with and in a same layer as the data lines and a plurality of second electrodes disposed parallel with the gate lines and in a same layer as the anode. At least one first electrode constitutes a touch driving line, and at least one second electrode constitutes a touch sensing line.

In at least one embodiment of the present disclosure, the base substrate has the plurality of first electrodes formed in the same layer as the data lines and the plurality of second electrodes formed in the same layer as the anode, at least one first electrode constitutes the touch driving line and at least one second electrode constitutes the touch sensing line, so that the base substrate has the touch sensors provided thereon and thus the In-cell touch technology is applicable to AMOLED displays fabricated with various processes.

For example, the first electrodes are arranged uniformly in a row direction, the second electrodes arc arranged uniformly in a column direction, and the first electrodes and the second electrodes are both disposed in the non-emission area of the array substrate. In the embodiments of the present disclosure, the first electrodes are arranged uniformly in the row direction and the second electrodes are arranged uniformly in the column direction, so that touch detection points are distributed uniformly and the accuracy of touch detection can be improved.

For example, at least one column of pixel units are provided between two adjacent first electrodes, and at least one row of pixel units are provided between two adjacent second electrodes. In the embodiments of the present disclosure, the distance between the adjacent first electrodes and the distance between the adjacent second electrodes are set flexibly to achieve touch detection with different precisions.

For example, two or more first electrodes constitute one touch driving line, and the two or more first electrodes constituting one touch driving line are connected with each other at their two ends; and two or more second electrodes constitute one touch sensing line, and the two or more second electrodes constituting one touch sensing line are connected with each other at their two ends. In the embodiments of the present disclosure, one touch driving line includes a plurality of first electrodes and one touch sensing line includes a plurality of second electrodes, so that the resistance of the touch driving lines and the resistance of the touch sensing lines can be reduced and the signal transmission efficiency can be improved.

For example, one column of pixel units are provided between two adjacent touch driving lines, and one row of pixel units are provided between two adjacent touch sensing lines. In the embodiments of the present disclosure, the distance between the adjacent touch driving lines and the distance between the adjacent touch sensing lines are set flexibly to achieve touch detection with different precisions.

For example, at least two columns of pixel units are provided between two adjacent touch driving lines, and at least one first electrode insulated from the touch driving line is disposed between two adjacent touch driving lines; and at least two rows of pixel units are provided between two adjacent touch sensing lines, and at least one second electrode insulated from the touch sensing line is disposed two adjacent touch sensing lines. In the embodiments of the present disclosure, at least one first electrode insulated from the touch driving lines is disposed between adjacent touch driving lines to prevent crosstalk between the touch driving lines, and at least one second electrode insulated from the touch sensing lines is disposed between adjacent touch sensing lines to prevent crosstalk between the touch sensing lines.

For example, 20-30 adjacent first electrodes constitute one touch driving line. In the embodiments of the present disclosure, the resistance of the touch driving lines is reduced while the touch detection precision are guaranteed.

For example, 5-15 adjacent second electrodes constitute one touch sensing line. In the embodiments of the present disclosure, the resistance of the touch sensing lines is reduced while the touch detection precisions are guaranteed.

For example, one touch sensing line comprises 5-15 adjacent second electrodes. In the embodiments of the present disclosure, the resistance of the touch sensing lines is reduced while the touch detection precisions are guaranteed.

At least one embodiment of the present disclosure provides a touch display panel, and the touch display panel comprises the array substrate as described above.

At least one embodiment of the present disclosure provides a touch display device, and the touch display device comprises the touch display panel as described above.

### BRIEF DESCRIPTION OF THE DRAWINGS

In order to clearly illustrate the technical solutions of embodiments of the present disclosure, the drawings for the embodiments will be briefly described in the following; it is obvious that the drawings to be described hereafter are only related to some embodiments of the present disclosure and thus are not limitative of the present disclosure.

FIG. 1 is a schematic view illustrating an array substrate according to embodiments of the present disclosure;

FIG. 2 is a top view of the array substrate having the first arrangement of touch driving lines and touch sensing lines according to the embodiments of the present disclosure;

FIG. 3 is a top view of the array substrate having the second arrangement of the touch driving lines and the touch sensing lines according to the embodiments of the present disclosure;

FIG. 4 is a top view of the array substrate having the third arrangement of the touch driving lines and the touch sensing lines according to the embodiments of the present disclosure; and

FIG. 5 is a schematic view illustrating another array substrate according to the embodiments of the present disclosure.

### DETAILED DESCRIPTION

In order to make objects, technical details and advantages of embodiments of the present disclosure apparent, the technical solutions of the embodiments will be described in a clearly and fully understandable way in connection with the drawings related to the embodiments of the present disclosure. It is obvious that the embodiments to be described are only some, not all, of the embodiments of the present disclosure. Based on the described embodiments herein, those skilled in the art can obtain other embodiments without any creative work, which fall within the scope claimed by the present the disclosure.

At least one embodiment of the present disclosure provides an array substrate, so that the In-cell touch technology is implemented in an AMOLED display and the implementation of the In-cell touch technology is not limited by the fabrication process of the display panel of the AMOLED display. For example, the array substrate includes a base substrate, and the base substrate has a plurality of pixel units formed by intersecting data lines and gate lines. The data lines and the gate lines are provided on the base substrate. Each pixel unit includes a bottom emission type OLED device and at least one thin film transistor (TFT), and the OLED device includes a transparent anode. The array substrate further includes a plurality of first electrodes disposed parallel with and in a same layer as the data lines, and a plurality of second electrodes disposed parallel with the gate lines and in a same layer as the anode. At least one first electrode constitutes a touch driving line, while at least one second electrode constitutes a touch sensing line.

It is to be noted that, each pixel unit of the array substrate may include one TFT or a plurality of TFTs, for example, a 2T1C control structure (in which 2 TFTs and 1 capacitor are provided) or a 6T2C control structure (in which 6 TFTs and 2 capacitors are provided) may be employed. Meanwhile, the TFT may be of bottom gate type or top gate type. The above-mentioned control structure or TFT exerts no influence on the configuration of the touch driving lines and the touch sensing lines, i.e. the embodiments of the disclosure are applicable to the array substrate in which each pixel unit includes one or more TFTs and the TFT is of top gate type or bottom gate type as described above, which will not be further described in detail here.

In at least one embodiment of the present disclosure, the base substrate has the plurality of first electrodes formed in the same layer as the data lines and the plurality of second electrodes formed in the same layer as the anode, at least one first electrode constitutes the touch driving line and at least one second electrode constitutes the touch sensing line, so that the base substrate 1 has the touch sensors provided thereon and thus the In-cell touch technology is applicable to AMOLED displays fabricated with various processes.

### Embodiment 1

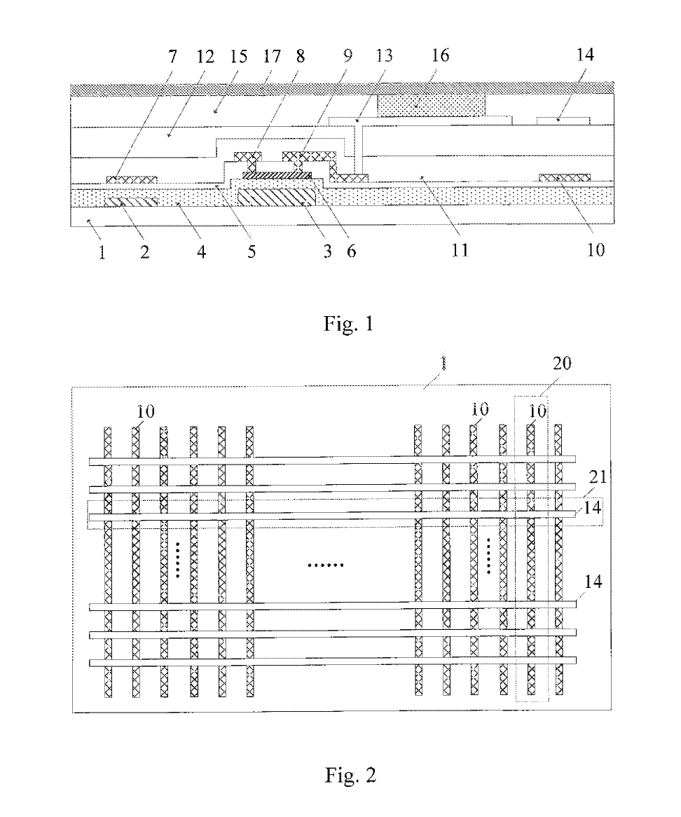

With reference to FIG. 1, for example, a relatively specific array substrate is illustrated. The array substrate includes a base substrate 1, a gate metal layer, a gate insulating layer 4, an active layer 5, an etching stop layer 6, a source/drain metal layer, a passivation layer 11, a flattening layer 12, an anode layer, a pixel defining layer 15, an organic light emitting layer 16 and a cathode 17 are formed in this order on the base substrate 1, the gate metal layer includes gate lines 2 and gate electrodes 3, the source/drain metal layer includes data lines 7, source electrodes 8 and drain electrodes 9, and the anode layer includes anodes 13. The gate electrodes 3, the gate insulating layer 4, the active layer 5, the etching stop layer 6, the source electrodes 8 and the drain electrodes 9 constitute bottom gate type TFTs, while the pixel defining layer 15, the organic light emitting layer 16, the anodes 13 and the cathode 17 constitute OLED devices. In the present embodiment, the case in which only one TFT is employed and such TFT is of bottom gate type is described as an example. However, in practical applications, a plurality of TFTs may be employed, and their structures may be the same as or different from that shown in FIG. 1, which will not be further described here.

In order to realize touch function, a plurality of first electrodes 10 are disposed in the source/drain metal layer and a plurality of second electrodes 14 are disposed in the anode layer. At least one first electrode 10 constitutes a touch driving line for transmitting touch driving signals and at least one second electrode constitutes a touch sensing line for transmitting touch sensing signals, so that the base substrate 1 has touch sensors provided thereon and thus the In-cell technology is applicable to AMOLED displays fabricated with various processes.

For example, the first electrodes 10 are arranged uniformly in a row direction, and the second electrodes 14 are arranged uniformly in a column direction. The first electrodes 10 and the second electrodes 14 are both disposed in the non-emission area of the array substrate. In the embodiment of the present disclosure, the first electrodes 10 are arranged uniformly in the row direction and the second electrodes 14 are arranged uniformly in the column direction, so that touch detection points are distributed uniformly and the accuracy of touch detection can be improved. For example, at least one column of pixel units are provided between two adjacent first electrodes 10, and at least one row of pixel units are provided between two adjacent second electrodes 14. In the embodiment of the present disclosure, the distance between the adjacent first electrodes 10 and the distance between the adjacent second electrodes 14 are set flexibly to achieve touch detection with different precisions.

FIG. 2 shows a top view of the array substrate, in which only the base substrate 1, the first electrodes 10 and the second electrodes 14 are illustrated for simplicity. The first electrodes 10 are uniformly arranged in the row direction and the second electrodes 14 are uniformly arranged in the column direction, and the first electrodes 10 and the second electrodes 14 are both disposed in the non-emission area of the array substrate. For example, one first electrode 10 constitutes one touch driving line 20 and one second electrode 14 constitutes one touch sensing line 21.

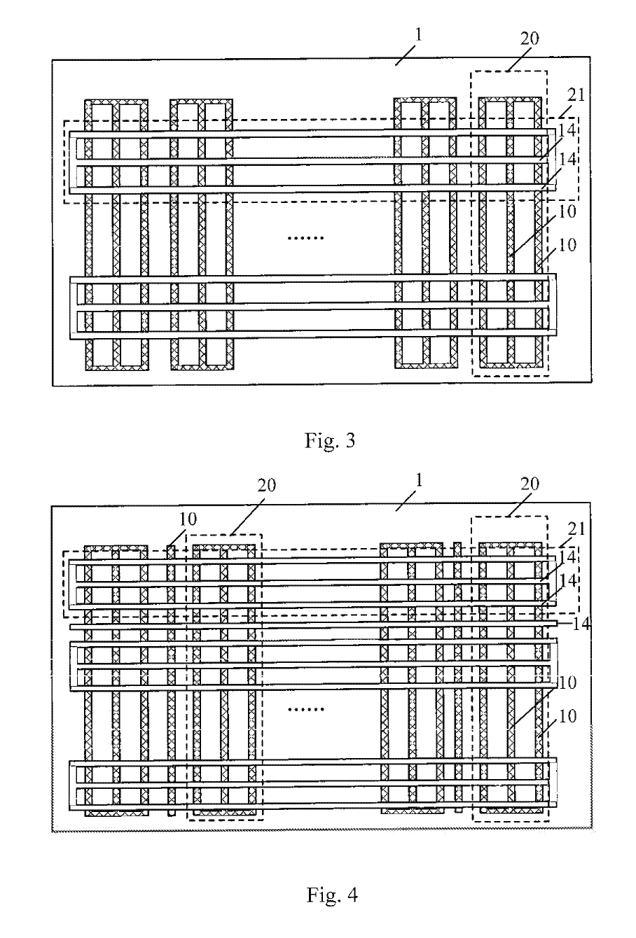

FIG. 3 shows a top view of the array substrate, in which only the base substrate 1, the first electrodes 10 and the second electrodes 14 are illustrated for simplicity. The first electrodes 10 are uniformly arranged in the row direction and the second electrodes 14 are uniformly arranged in the column direction, and the first electrodes 10 and the second electrodes 14 are both disposed in the non-emission area of the array substrate. For example, three first electrodes 10 are connected with one another at their two ends to constitute one touch driving line 20, and three second electrodes 14 are connected with one another at their two ends to constitute one touch sensing line 21. Of course, one touch driving line 20 may be constituted by two first electrodes 10 connected with each other at their two ends, and one touch sensing line 21 may be constituted by two second electrodes 14 connected with each other at their two ends; or one touch driving line 20 may be constituted by more than three first electrodes 10 connected with one another at their two ends, and one touch sensing line 21 may be constituted by more than three second electrodes 14 connected with one another at their two ends. The number of the first electrodes 10 for constituting one touch driving line 20 may be the same as or different from the number of the second electrodes 14 for constituting one touch sensing line 21, which will not be further described here. In at least one embodiment of the present disclosure, one touch driving line 20 includes a plurality of first electrodes 10 and one touch sensing line 21 includes a plurality of second electrodes 14, so that the resistance of the touch driving lines 20 and the touch sensing lines 21 can be reduced and the signal transmission efficiency can be improved.

In at least one embodiment of the present disclosure, for example, one column of pixel units (not shown) are provided between two adjacent touch driving lines 20, while one row of pixel units (not shown) are provided between two adjacent touch sensing lines 21. In at least one embodiment of the present disclosure, for example, the distance between adjacent touch driving lines 20 are set flexibly (that is, two or more columns of pixel units may be provided between two adjacent touch driving lines 20), and the distance between adjacent touch sensing lines 21 are set flexibly (that is, two or more rows of pixel units may be provided between two adjacent touch sensing lines 21), so as to achieve touch detection with different precisions.

Generally, there may be crosstalk between the touch driving lines 20 and between the touch sensing lines 21. In order to reduce such crosstalk, at least two columns of pixel units are provided between two adjacent touch driving lines 20, and at least one first electrode 10 insulated from the touch driving lines 20 is disposed between two adjacent touch driving lines 20; similarly, at least two rows of pixel units are provided between two adjacent touch sensing lines 21, and at least one second electrode 14 insulated from the touch sensing lines 21 is disposed two adjacent touch sensing lines 21. FIG. 4 shows a top view of the array substrate, in which only the base substrate 1, the first electrodes 10 and the second electrodes 14 are illustrated for simplicity. The first electrodes 10 are uniformly arranged in the row direction and the second electrodes 14 are uniformly arranged in the column direction, and the first electrodes 10 and the second electrodes 14 are both disposed in the non-emission area of the array substrate. One touch driving line 20 is constituted by three first electrodes 10 connected with one another at their two ends and one first electrode 10 insulated from the touch driving lines 20 is disposed between two adjacent touch driving lines 20; one touch sensing line 21 is constituted by three second electrodes 14 connected with one another at their two ends and one second electrode 14 insulated from the touch sensing lines 21 is disposed between two adjacent touch sensing lines 21.

In the embodiment of the present disclosure, at least one first electrode 10 insulated from the touch driving lines 20 is disposed between adjacent touch driving lines 20 to prevent crosstalk between the touch driving lines 20, and at least one second electrode 14 insulated from the touch sensing lines 21 is disposed between adjacent touch sensing lines 21 to prevent crosstalk between the touch sensing lines 21.

In at least one embodiment of the present disclosure, for example, 20-30 adjacent first electrodes 10 constitute one touch driving line 20 while 5-15 adjacent second electrodes 14 constitute one touch sensing line 21, the illustration of such structure can be obtained with reference to FIG. 2 and FIG. 4, because such structure is similar to those in FIG. 2 and FIG. 4 except that the number of the first electrodes 10 constituting one touch driving line 20 is changed and the number of the second electrodes 14 constituting one touch sensing line 21 is changed. In the embodiment of the present disclosure, the resistance of the touch driving lines 20 and the resistance of the touch sensing lines 21 can be reduced while the touch detection precision can be guaranteed.

The beneficial effects of the embodiment of the present disclosure are as follows. The plurality of first electrodes 10 are formed in the same layer as the data lines 7 and the plurality of second electrodes 14 are formed in the same layer as the anodes 13, at least one first electrode 10 constitutes the touch driving line 20, and at least one second electrode constitutes the touch sensing line 21, so that the base substrate 1 has touch sensors provided thereon, and thus the In-cell technology is applicable to AMOLED displays fabricated with various processes. Furthermore, tow or more first electrodes 10 constitute one touch driving lines 20, and two or more second electrodes 14 constitute one touch sensing lines 21, so that resistance of the touch driving lines 20 and the resistance of the touch sensing lines 21 are reduced. In addition, at least one first electrode 10 insulated from the touch driving lines 20 is disposed between adjacent touch driving lines 20 to reduce crosstalk between the touch driving lines 20, and at least one second electrode 14 insulated from the touch sensing lines 21 is disposed between adjacent touch sensing lines 21 to reduce crosstalk between the touch sensing lines 21.

### Embodiment 2

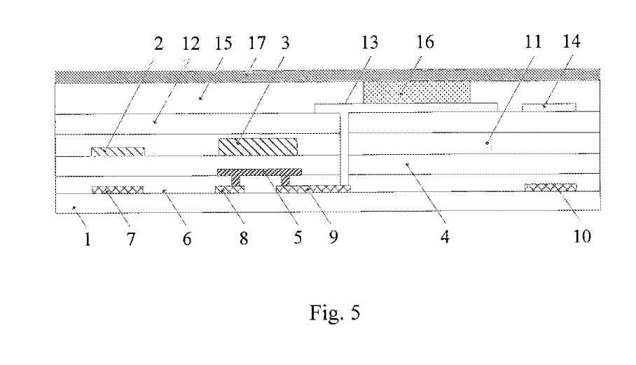

With reference to FIG. 5, another relatively specific array substrate is illustrated. The array substrate includes a base substrate 1, and a source/drain metal layer, an etching stop layer 6, an active layer 5, a gate insulating layer 4, a gate metal layer, a passivation layer 11, a flattening layer 12, an anode layer, a pixel defining layer 15, an organic light emitting layer 16 and a cathode 17 are formed in this order on the base substrate 1. The gate metal layer includes gate lines 2 and gate electrodes 3, the source/drain metal layer includes data lines 7, source electrodes 8 and drain electrodes 9, and the anode layer includes anodes 13. The gate electrodes 3, the gate insulating layer 4, the active layer 5, the etching stop layer 6, the source electrodes 8 and the drain electrodes 9 constitute top gate type TFTs, and the pixel defining layer 15, the organic light emitting layer 16, the anodes 13 and the cathode 17 constitute OLED devices. In the present embodiment, the case in which only one TFT is employed is described as an example. However, in practical applications, a plurality of TFTs may be employed, and their structures may be the same as or different from that shown in this figure, which will not be further described here.

In order to realize touch function, a plurality of first electrodes 10 are disposed in the source/drain metal layer and a plurality of second electrodes 14 are disposed in the anode layer. With reference to FIG. 2 and FIG. 4, at least one first electrode 10 constitutes the touch drive line 20 for transmitting touch driving signals and at least one second electrode 14 constitutes the touch sensing line 21 for transmitting touch sensing signals, so that the base substrate 1 has touch sensors provided thereon and thus the hi-cell technology is applicable to AMOLED displays fabricated with various processes. The array substrate shown in FIG. 5 is only different from that shown in FIG. 1 in the structure of the TFTs. The touch driving lines 20 and the touch sensing lines 21 of the array substrate shown in FIG. 5 have the same arrangement as those shown in FIG. 2 to FIG. 4, and the descriptions thereof will be the same as those in embodiment 1 and will not be repeated here.

At least one embodiment of the present disclosure provides a touch display panel, and the touch display panel includes the array substrate according to the above embodiments. In the touch display panel, the touch driving lines and the touch sensing lines are both connected to the touch processing chip; or the touch driving lines are connected to the touch signal transmitter and the touch sensing lines are connected to the touch signal receiver, which will not be detailed here.

The beneficial effects of the embodiments of the present disclosure are as follows. The plurality of first electrodes are formed in the same layer as the data lines and the plurality of second electrodes are formed in the same layer as the anodes, at least one first electrode constitutes the touch driving line, and at least one second electrode constitutes the touch sensing line, so that the base substrate 1 has touch sensors provided thereon, and thus the In-cell technology is applicable to AMOLED displays fabricated with various processes. Furthermore, tow or more first electrodes constitute one touch driving lines, and two or more second electrodes constitute one touch sensing lines, so that resistance of the touch driving lines and the resistance of the touch sensing lines are reduced. In addition, at least one first electrode insulated from the touch driving lines is disposed between adjacent touch driving lines to reduce crosstalk between the touch driving lines, and at least one second electrode insulated from the touch sensing lines is disposed between adjacent touch sensing lines to reduce crosstalk between the touch sensing lines.

At least one embodiment of the present disclosure provides a touch display device, and the touch display device includes the touch display panel according to the above embodiments.

The beneficial effects of the embodiments of the present disclosure are as follows. The plurality of first electrodes are formed in the same layer as the data lines and the plurality of second electrodes are formed in the same layer as the anodes, at least one first electrode constitutes the touch driving line, and at least one second electrode constitutes the touch sensing line, so that the base substrate 1 has touch sensors provided thereon, and thus the In-cell technology is applicable to AMOLED displays fabricated with various processes. Furthermore, tow or more first electrodes constitute one touch driving lines, and two or more second electrodes constitute one touch sensing lines, so that resistance of the touch driving lines and the resistance of the touch sensing lines are reduced. In addition, at least one first electrode insulated from the touch driving lines is disposed between adjacent touch driving lines to reduce crosstalk between the touch driving lines, and at least one second electrode insulated from the touch sensing lines is disposed between adjacent touch sensing lines to reduce crosstalk between the touch sensing lines.

The foregoing embodiments merely are exemplary embodiments of the disclosure, and not intended to define the scope of the disclosure, and the scope of the disclosure is determined by the appended claims.

The present application claims priority of Chinese Patent Application No. 201410749101.9 filed on Dec. 9, 2014, the disclosure of which is incorporated herein by reference in its entirety as part of the present application.

1. An array substrate, comprising:
a base substrate, wherein the base substrate has a plurality of pixel units formed by intersecting data lines and gate lines, the data lines and the gate lines are provided on the base substrate, each pixel unit comprises a bottom emission type organic light emitting diode (OLED) device and at least one thin film transistor (TFT), and the OLED device includes a transparent anode;
a plurality of first electrodes disposed parallel with and in a same layer as the data lines, and
a plurality of second electrodes disposed parallel with the gate lines and in a same layer as the anode,
wherein at least one first electrode constitutes a touch driving line, and at least one second electrode constitutes a touch sensing line.

2. The array substrate according to claim 1, wherein
the first electrodes are arranged uniformly in a row direction, the second electrodes are arranged uniformly in a column direction, and the first electrodes and the second electrodes are both disposed in a non-emission area of the array substrate.

3. The array substrate according to claim 2, wherein
at least one column of pixel units are provided between two adjacent first electrodes, and at least one row of pixel units are provided between two adjacent second electrodes.

4. The array substrate according to claim 1, wherein
two or more first electrodes constitute one touch driving line, and the two or more first electrodes constituting one touch driving line are connected with each other at their two ends; and
two or more second electrodes constitute one touch sensing line, and the two or more second electrodes constituting one touch sensing line are connected with each other at their two ends.

5. The array substrate according to claim 1, wherein
one column of pixel units are provided between two adjacent touch driving lines, and one row of pixel units are provided between two adjacent touch sensing lines.

6. The array substrate of according to claim 1, wherein
at least two columns of pixel units are provided between two adjacent touch driving lines, and at least one first electrode insulated from the touch driving line is disposed between two adjacent touch driving lines; and,
at least two rows of pixel units are provided between two adjacent touch sensing lines, and at least one second electrode insulated from the touch sensing line is disposed two adjacent touch sensing lines.

7. The array substrate according to claim 4, wherein 20-30 adjacent first electrodes constitute one touch driving line.

8. The array substrate according to claim 4, wherein 5-15 adjacent second electrodes constitute one touch sensing line.

9. A touch display panel, comprising the array substrate according to claim 1.

10. A touch display device, comprising the touch display panel according to claim 9.

11. The array substrate according to claim 2, wherein
two or more first electrodes constitute one touch driving line, and the two or more first electrodes constituting one touch driving line are connected with each other at their two ends; and
two or more second electrodes constitute one touch sensing line, and the two or more second electrodes constituting one touch sensing line are connected with each other at their two ends.

12. The array substrate according to claim 3, wherein
two or more first electrodes constitute one touch driving line, and the two or more first electrodes constituting one touch driving line are connected with each other at their two ends; and
two or more second electrodes constitute one touch sensing line, and the two or more second electrodes constituting one touch sensing line are connected with each other at their two ends.

13. The array substrate according to claim 2, wherein
one column of pixel units are provided between two adjacent touch driving lines, and one row of pixel units are provided between two adjacent touch sensing lines.

14. The array substrate according to claim 3, wherein
one column of pixel units are provided between two adjacent touch driving lines, and one row of pixel units are provided between two adjacent touch sensing lines.

15. The array substrate according to claim 4, wherein
one column of pixel units are provided between two adjacent touch driving lines, and one row of pixel units are provided between two adjacent touch sensing lines.

16. The array substrate of according to claim 2, wherein
at least two columns of pixel units are provided between two adjacent touch driving lines, and at least one first electrode insulated from the touch driving line is disposed between two adjacent touch driving lines; and,
at least two rows of pixel units are provided between two adjacent touch sensing lines, and at least one second electrode insulated from the touch sensing line is disposed two adjacent touch sensing lines.

17. The array substrate of according to claim 3, wherein
at least two columns of pixel units are provided between two adjacent touch driving lines, and at least one first electrode insulated from the touch driving line is disposed between two adjacent touch driving lines; and,
at least two rows of pixel units are provided between two adjacent touch sensing lines, and at least one second electrode insulated from the touch sensing line is disposed two adjacent touch sensing lines.

18. The array substrate of according to claim 4, wherein
at least two columns of pixel units are provided between two adjacent touch driving lines, and at least one first electrode insulated from the touch driving line is disposed between two adjacent touch driving lines; and,
at least two rows of pixel units are provided between two adjacent touch sensing lines, and at least one second electrode insulated from the touch sensing line is disposed two adjacent touch sensing lines.
